(19) United States
(12) Patent Application Publication
(10) Pub. No.: US 2010/0321908 A1
(43) Pub. Date: Dec. 23, 2010

(54) ELECTRONIC CIRCUIT DEVICE, PRODUCTION METHOD THEREOF, AND DISPLAY DEVICE

(76) Inventor: Motoji Shiota, Tsu-shi (JP)

Correspondence Address: BIRCH STEWART KOLASCH & BIRCH, PO BOX 747, FALLS CHURCH, VA, 22040-0747, US

(21) Appl. No.: 12/517,996

(22) PCT Filed: Oct. 19, 2007
(86) PCT No.: PCT/JP2007/070471

§ 371 Date: Jun. 5, 2009

(30) Foreign Application Priority Data
Feb. 22, 2007 (JP) 2007 042701

(51) Int. Cl. H05K 1/18; H05K 3/30

(52) U.S. Cl. 361/771; 29/832

(57) ABSTRACT

The present invention provides an electronic circuit device that can be downsized, a production method thereof, and a display device. The present invention is an electronic circuit device including:
an electronic first component;
an electronic second component;
an electronic third component;
an anisotropic first conductive layer; and
an anisotropic second conductive layer,
wherein the electronic first component is connected to the electronic third component via the anisotropic first conductive layer, and
the electronic second component is connected to the electronic third component via the anisotropic first conductive layer and the anisotropic second conductive layer,
the anisotropic first conductive layer and the anisotropic second conductive layer being stacked in this order on the electronic third component.

### TECHNICAL FIELD

The present invention relates to an electronic circuit device, a production method thereof, and a display device. More particularly, the present invention relates to an electronic circuit device that includes electronic components electrically connected to each other via an anisotropic conductive material, and to a production method thereof, and further to a display device.

### BACKGROUND ART

Anisotropic conductive materials are now being used as a member for connecting two opposing electronic components each including many electrodes to each other. Such anisotropic conductive materials are connection materials that electrically connect the electronic components to each other while the two opposing electrodes are electrically to each other and two adjacent electrodes are insulated from each other, and further the anisotropic conductive materials are connection materials that can mechanically fix the electronic components to each other. Using these anisotropic conductive materials, a semiconductor element such as a semiconductor integrated circuit (hereinafter, also referred to as an “IC”) and a large scale integrated circuit (hereinafter, also referred to as an “LSI”) can be mounted on a wiring board such as a printed board, and a substrate constituting a liquid crystal display panel.

A conventional technology for mounting an IC and a flexible printed circuit board (hereinafter, also referred to as an FPC board) on a glass substrate constituting a liquid crystal display panel are mentioned below. FIG. 4 is a schematic view showing a mounting structure of electronic components in a conventional liquid crystal display panel. FIG. 4(a) is a perspective view schematically showing the mounting structure. FIG. 4(b) is a cross-sectional view showing the mounting structure taken along line P-Q in FIG. 4(a). According to a conventional liquid crystal display panel 36, as shown in FIG. 4, a driving IC 28 and a FPC board 30 are mounted on an extending part 22 of a glass substrate (TFT array substrate) 39a that is one substrate constituting the liquid crystal display panel 36. More specifically, circuit wirings 23 and 24 are arranged on the driving IC 28 and FPC board 30 side of extending part 22 of the glass substrate 39a. The driving IC 28 includes a bump electrode 29 on the glass substrate 39a side. The FPC board 30 includes a lead electrode 31 and a base material 32, and the lead electrode 31 is arranged on the base material 32. An anisotropic conductive layer 33a, which is a cured product of an anisotropic conductive material, is arranged on the glass substrate 39a in at least a region where the circuit wirings 23 and 24 are arranged. An anisotropic conductive layer 33b, which is a cured product of an anisotropic conductive material, is arranged on the glass substrate 39a to overlap with the circuit wiring 24. The anisotropic conductive layer 33a is formed of an epoxy resin into which conductive particles 34a have been dispersed and the anisotropic conductive layer 33b is formed of an epoxy resin into which conductive particles 34b have been dispersed, for example. The anisotropic conductive layers 33a and 33b show conductivity in the thickness direction and show insulating properties in the planar direction. The bump electrode 29 of the driving IC 28 is electrically connected to the circuit wirings 23 and 24 via the conductive particles 34a. Further, the driving IC 28 is fixed to the glass substrate 39a by the resin contained in the anisotropic conductive layer 33a. The lead electrode 31 of the FPC board 30 is electrically connected to the circuit wiring 24 via the conductive particles 34b contained in the anisotropic conductive layer 33b. The FPC board 30 is fixed to the glass substrate 39a, similarly to the driving IC 28.

A conventional method for producing the above-mentioned liquid crystal display panel 36 is mentioned below. The liquid crystal display panel 36 including the circuit wirings 23 and 24 arranged on the glass substrate 39a (liquid crystals 38 are sealed between the glass substrates 39a and 39b with a sealing member 37), first. An anisotropic conductive material (a material that forms the anisotropic conductive layer 33a by being cured) such as an anisotropic conductive film (hereinafter, also referred to as an “ACF”) is provided in a region where the circuit wirings 23 and 24 are arranged on the glass substrate 39a. The bump electrode 29 of the driving IC 28 is aligned to the circuit wirings 23 and 24 and then the driving IC 28 is thermocompression-bonded to the circuit wirings 23 and 24 under specific conditions. Then, similarly, an anisotropic conductive material (a material that forms the anisotropic conductive layer 33b by being cured) such as an ACF is provided in a region where the circuit wiring 24 is arranged, and then the FPC board 30 is thermocompression-bonded to the circuit wiring 24. Thus, external circuits such as the driving IC 28 and the FPC board 30 can be mounted on the liquid crystal display panel 36.

Downsizing is strongly needed for electronic devices such as a TV, a display for PCs, and a display for PDAs, and a region outside a display region of these devices needs to be further decreased. It is important how much a region (frame region) where external circuits such as a driving IC and a flexible printed board are mounted is reduced.

However, according to the conventional liquid crystal display panel 36, there is a possibility that the driving IC 28 and the FPC board 30 might be misaligned when being mounted on the panel, and so, regions where the anisotropic conductive layers 33a and 33b are arranged are larger than those where the driving IC 28 and the FPC board 30 are actually mounted, respectively. In addition, the anisotropic layers 33a and 33b need to be arranged with a distance therebetween. The reason for this is mentioned below. If an ACF is arranged below a component different from a component below which this ACE should be positioned, compression bonding might be performed in an unbalanced manner and components might be insufficiently compression-bonded to the panel. In addition, even if an ACF is not arranged below a component different from the proper component, a uniform pressure is not applied when the ACFs partly overlap with each other and as a result, the components are not sufficiently fixed to the panel. Accordingly, if accuracy when the respective anisotropic conductive layers 33a and 33b are arranged is taken into consideration, the driving IC 28 and the FPC board 30 need to be arranged with a minimum distance A2 (for example, at least 0.4 mm or more) therebetween. So according to the conventional liquid crystal display panel 36, the reduction in frame region has a limitation.

Under such a circumstance, in order to improve productivity, a production yield and to simplify production processes, a technology for mounting different external circuits such as a driving IC and a FPC board using the same ACF is disclosed.

More specifically, for example, Patent Document 1 discloses an electro-optic device where an integrated circuit chip is electrically connected to a wiring pattern via an anisotropic conductive film, and the anisotropic conductive film is formed to cover a connecting wiring part.

In addition, for example, Patent Document 2 discloses a display device where two different components are mounted on at least one substrate constituting a display panel via one anisotropic conductive film.

In addition, for example, Patent Document 3 discloses a method for mounting a panel, including the steps of providing anisotropically conductive material to a closed region including plural points to be mounted with parts of a panel including circuit wirings; and thermocompression-bonding the parts to the circuit wirings via the anisotropically conductive material.

However, the external circuits to be mounted (components to be bonded) have different characteristics. Particularly between a driving IC and a FPC board, characteristics such as hardness (hard or soft) and material (silicon material or polyimide film) are different. Accordingly, it is difficult to develop an anisotropic conductive film that can be used commonly to a plurality of external circuits including a plurality of different electronic components. That is, if the conventional ACF is used commonly to the plurality of different electronic components, a component is sufficiently electrically connected and fixed to another component, but another one is insufficient. Thus, the conventional device or method has room for improvement in that reliability of the mounting structure of the electronic components in the electronic circuit device is improved.

For this problem, for example, Patent Document 4 discloses an adhesive sheet prepared by connecting and integrating a plurality of sheets with each other, as an adhesive sheet used for mounting a plurality of different circuit boards on a substrate. According to this, an ACF for a driving IC and an ACF for a FPC board can be integrated with each other. However, in order to provide this adhesive sheet, a problem in view of technology and costs rises, and accuracy when this adhesive sheet is attached needs to be improved.

For example, Patent Document 5 discloses the following liquid crystal display device: an electrode for panel connection and an anisotropic conductive film for connecting a pattern electrode for external circuit connection to a driving IC are arranged; a flexible printed board is arranged on the rear face of the driving IC with a thermosetting anisotropic conductive film therebetween; the flexible printed board is connected to the pattern electrode for external circuit connection via a conductive pattern on the rear side face of the driving IC. Patent Document 5 discloses that the pattern electrode for external circuit connection can be shortened, but it is very difficult in view of technology to provide such a liquid crystal display device. In this liquid crystal display device, the ACF used for connecting the pattern for external circuit connection to the driving IC is not arranged between the pattern on the rear face and the flexible printed board.

In addition, Patent Document 6 shows a technology for downsizing dimensions of a panel using a conductive member such as an anisotropic conductive member for connecting a FPC to a display panel, and connecting the FPC to a wiring board. However, this technology relates to a TCP (tape carrier package) technology and the panel (substrate) size cannot be reduced, and accordingly, in order to reduce a mounting region (frame region), there is room for further improvement.

For example, patent Document 7 discloses a technology of electrically connecting all of scanning electrodes and signal electrodes to an external electrode board via an anisotropic conductive film, in a liquid crystal panel including three stacked layers as a liquid crystal layer, as a technology of using an anisotropic conductive film in a liquid crystal panel.

For example, Patent Document 8 discloses, as a method of connecting semiconductor elements to each other via an anisotropic conductive film, a method of: transferring anisotropic conductive films to two semiconductor elements, respectively, so that the thickness of each of the anisotropic conductive films is not uniform; attaching and bonding the two semiconductor elements to each other with the anisotropic conductive films so that the anisotropic conductive films are united into one having a uniform thickness.

Further, Patent Document 9 discloses the following multilayered anisotropic conductive film laminate: a release film contains no silicone and has a tensile strength of 10 kN/cm² or more and a surface tension of 350 μN/cm² or less; a peel strength of a first anisotropic conductive film that is in contact with the release film is 2 N/5 cm or less and larger than that of a second anisotropic conductive film that is in contact with the rear surface of the release film by 0.05 N/5 cm or more. According to this, ACFs different in sealing property to the release film are laminated and the laminate is provided at one time. According to this multilayered anisotropic conductive film laminate, blocking of the ACF when the ACF is winded back from a real is suppressed and the release property of the ACF can be secured.
[Patent Document 1]
Japanese Kokai Publication No. 2001-242799
[Patent Document 2]
Japanese Kokai Publication No. 2002-305220
[Patent Document 3]
Japanese Kokai Publication No. Hei-05-313178
[Patent Document 4]
Japanese Kokai Publication No. 2006-56995
[Patent Document 5]
Japanese Kokai Publication No. Hei-09-101533
[Patent Document 6]
Japanese Kokai Publication No. 2000-347593
[Patent Document 7]
Japanese Kokai Publication No. Hei-10-228028
[Patent Document 8]
Japanese Kokai Publication No. Hei-10-145026
[Patent Document 9]
Japanese Kokai Publication No. 2001-171033

### DISCLOSURE OF INVENTION

The present invention has been made in view of the above-mentioned state of the art. The present invention has an object to provide an electronic circuit device that can be downsized and a production method of such a device.

The present inventors made various investigations on an electronic circuit device that can be downsized. The inventors noted an arrangement configuration of an anisotropic conductive layer. The inventors found that the electronic circuit device can be downsized when an electronic first component is connected to an electronic third component via an anisotropic first conductive layer, an electronic second component is connected to the electronic third component via the anisotropic first conductive layer and an anisotropic second conductive layer, stacked in this order on the electronic third component side. As a result, the above-mentioned problems have been admirably solved, leading to completion of the present invention.

That is, the present invention is an electronic circuit device including:

an electronic first component;

an electronic second component;

an electronic third component;

an anisotropic first conductive layer; and

an anisotropic second conductive layer,

wherein the electronic first component is connected to the electronic third component via the anisotropic first conductive layer, and

the electronic second component is connected to the electronic third component via the anisotropic first conductive layer and the anisotropic second conductive layer,

the anisotropic first conductive layer and the anisotropic second conductive layer being stacked in this order on the electronic third component. According to this, there is no need to take accuracy when anisotropic conductive materials that are materials for the anisotropic first and second conductive layers are provided into consideration in production processes. Accordingly, the distance between the electronic first component and the electronic second component can be decreased, which leads to downsizing of the electronic circuit device.

The anisotropic first conductive layer and the anisotropic second conductive layer show conductivity in the thickness direction and show insulating properties in the planar direction. The anisotropic first conductive layer is generally arranged to cover a region where the electronic first component faces the electronic third component and a region where the electronic second component faces the electronic third component. The anisotropic second conductive layer is generally arranged to cover a region where the electronic second component faces the electronic third component. Thus, it is preferable that the anisotropic first conductive layer is arranged to cover at least the region where the electronic first component faces the electronic third component and the region where the electronic second component faces the electronic third component, and that the anisotropic second conductive layer is arranged to cover at least the region where the electronic second component faces the electronic third component except for the region where the electronic first component faces the electronic third component.

Thus, the present invention may be an electronic circuit device including: three or more different electronic components including an electronic first component, an electronic second component, an electronic third component; and anisotropic conductive layers including an anisotropic first conductive layer and an anisotropic second conductive layer, the electronic first component and the electronic second component being electrically and mechanically connected to the electronic third component via the anisotropic conductive layers, wherein the anisotropic first conductive layer and the anisotropic second conductive layer are stacked, the anisotropic first conductive layer being arranged on the electronic third component side in the thickness direction, the anisotropic second conductive layer being arranged on the electronic second component side in the thickness direction, and the anisotropic first conductive layer is arranged to cover a region where the electronic first component and the electronic second component are to be arranged (mounted), and the anisotropic second conductive layer is arranged to cover a region where the electronic second component is to be arranged (mounted). Alternatively, the present invention may be an electronic circuit device including: three or more different electronic components including an electronic first component, an electronic second component, an electronic third component; and anisotropic conductive layers including an anisotropic first conductive layer and an anisotropic second conductive layer, the electronic first component and the electronic second component being electrically and mechanically connected to the electronic third component via the anisotropic conductive layers, wherein the anisotropic first conductive layer and the anisotropic second conductive layer are stacked, the anisotropic first conductive layer being arranged on the electronic third component side in the thickness direction, the anisotropic second conductive layer being arranged on the electronic second component side in the thickness direction, and the anisotropic first conductive layer is arranged to cover at least a region where the electronic first component and the electronic second component are to be arranged (mounted), and the anisotropic second conductive layer is arranged to cover at least a region where the electronic second component is to be arranged (mounted) except for a region where the electronic first component is arranged (mounted).

Examples of the electronic first to third components include active elements, passive elements (chip components), an assembly of integrated passive elements, and wiring boards (circuit boards). Examples of the active elements include semiconductor elements such as a semiconductor IC (integrated circuit) and an LSI (large scale integrated circuit). Examples of the passive elements include an LED (light-emitting diode), a condenser, and a sensor. Specific examples of the wiring board include: printed boards such as a PWB (printed wiring board) and a FPC board; and substrates constituting a display panel such as a liquid crystal display panel. Thus, the wiring board is generally an electronic component where wirings are arranged on and/or in an insulating substrate (base material). The PWB may be what is so-called a PCB (printed circuit board).

The configuration of the electronic circuit device of the present invention is not especially limited, and the device may or may not include other components as long as it essentially includes such components. Preferable embodiments of the electronic circuit device of the present invention are mentioned in detail below. Various embodiments mentioned below may be employed in combination.

The kind of the electronic first and second components is not especially limited, but it is preferable that the electronic first component and the electronic second component are different in kind. It is particularly difficult to mount different components with a smaller distance therebetween. However, according to the present invention, the electronic circuit device can be downsized even if the different two electronic components, the electronic first component and the electronic second component, are mounted on the electronic third component. Accordingly, in this embodiment, the advantages of the present invention can be more remarkably exhibited.

The kind of the electronic third component is not especially limited, but it is preferably that the electronic third component is a wiring board. Thus, it is preferable that the electronic circuit device of the present invention has a structure in which at least two different electronic components are mounted on a wiring board, which is the electronic third component, via anisotropic conductive layers.

It is preferable that one of the electronic first component and the electronic second component is an active element and the other is a printed board, and the electronic third component is a wiring board when the electronic circuit device of the present invention is used as a control device for display devices such as a liquid crystal display device. As a result, the frame region of the display device can be decreased. More specifically, it is more preferable that one of the electronic first component and the electronic second component is a semiconductor element and the other is a flexible printed board, and the electronic third component is a substrate constituting a panel. In this case, the electronic circuit device of the present invention may have an embodiment in which the electronic first component is a semiconductor element and the electronic second component is a flexible printed board, or may have an embodiment in which the electronic first component is a flexible printed board and the electronic second component is a semiconductor element.

It is preferable that the anisotropic first conductive layer and the anisotropic second conductive layer are different in kind. It is preferable that the anisotropic first conductive layer and the anisotropic second conductive layer are different in property and/or material. As a result, the characteristics of the anisotropic first conductive layer and the anisotropic second conductive layer are individually adjusted in accordance with a kind, a surface configuration, and the like, of the electronic first and second components. That is, a material excellent in adhesion to the electronic first component can be used as a material for the anisotropic first conductive layer (hereinafter, also referred to as an “anisotropic first conductive material”), and a material excellent in adhesion to the electronic second component can be used as a material for the anisotropic second conductive layer (hereinafter, also referred to as an “anisotropic second conductive material”). As a result, the adhesion between the electronic first and second components and the electronic third component can be improved, which might result in an improvement in reliability of the electronic circuit device.

It is preferable that the electronic first component and the electronic second component are different in surface configuration. Thus, if two electronic components different in surface configuration are mounted, it has been difficult to use a material common to the two electronic component as the anisotropic conductive material, so far. However, in the present invention, the anisotropic first and second conductive layers may be different in property and/or material, and so the electronic first and second components can be mounted using the anisotropic first and second conductive materials having characteristics suitable for the electronic first and second components, respectively. So if the electronic first and second components different in surface configuration are mounted on the electronic third component, the reliability of the electronic circuit device can be more remarkably improved. The difference in surface configuration is preferably at least one difference in adhesion to the anisotropic conductive layer, the surface shape, and the surface material.

The property and material of the anisotropic first and second conductive layers are not especially limited. It is preferable that the anisotropic first conductive layer and the anisotropic second conductive layer are different in storage elastic modulus. According to this, the anisotropic first and second conductive layers that provide more excellent adhesion between the electronic first and second components and the electronic third component can be arranged. Accordingly, reliability of the electronic circuit device can be more improved. More specifically, it is preferable that one of the anisotropic first conductive layer and the anisotropic second conductive layer has a storage elastic modulus of 1.5 to 2.0×10⁹ Pa and the other has a storage elastic modulus of 1.2 to 1.3×10⁹ Pa. The anisotropic conductive layer having a storage elastic modulus of 1.5 to 2.0×10⁹ Pa is preferably used as an anisotropic conductive layer for an active element, particularly a semiconductor element. The anisotropic conductive layer having a storage elastic modulus of 1.2 to 1.3×10⁹ Pa is preferably used as an anisotropic conductive layer for a printed board, particularly a FPC board. Accordingly, the electronic circuit device including such anisotropic conductive layers is preferably used as a control device for display devices. If an anisotropic conductive layer having a storage elastic modulus of less than 1.5×10⁹ Pa or a storage elastic modulus of more than 2.0×10⁹ Pa is used, an active element, particularly a semiconductor element might not be reliably mounted on the electronic third component. If an anisotropic conductive layer having a storage elastic modulus of less than 1.2×10⁹ Pa or a storage elastic modulus of more than 1.3×10⁹ Pa is used, a printed board, particularly a FPC board might not be reliably mounted on the electronic third component. The electronic circuit device of the present invention may have an embodiment in which the anisotropic first conductive layer has a storage elastic modulus of 1.5 to 2.0×10⁹ Pa and the anisotropic second conductive layer has a storage elastic modulus of 1.2 to 1.3×10⁹ Pa or an embodiment in which the anisotropic first conductive layer has a storage elastic modulus of 1.2 to 1.3×10⁹ Pa and the anisotropic second conductive layer has a storage elastic modulus of 1.5 to 2.0×10⁹ Pa.

If the electronic circuit device of the present invention is used as a control device for display devices, the following embodiments are preferable. An embodiment in which: the electronic first component is a semiconductor element; the electronic second component is a flexible printed board; and the electronic third component is a substrate constituting a panel; the anisotropic first conductive layer has a storage elastic modulus of 1.5 to 2.0×10⁹ Pa; and the anisotropic second conductive layer has a storage elastic modulus of 1.2 to 1.3×10⁹ Pa. An embodiment in which: the electronic first component is a flexible printed board; the electronic second component is a semiconductor element; the electronic third component is a substrate constituting a panel; the anisotropic first conductive layer has a storage elastic modulus of 1.2 to 1.3×10⁹ Pa; and the anisotropic second conductive layer has a storage elastic modulus of 1.5 to 2.0×10⁹ Pa.

The materials for the anisotropic first and second conductive layers (the anisotropic first and second conductive materials) are not especially limited. Anisotropic conductive paste (liquid) materials (ACP), anisotropic conductive film materials (ACF), and the like, are mentioned as the materials for the anisotropic first and second conductive layers. However, it is preferable that the anisotropic conductive layer is made of an anisotropic conductive film material, in view of simplification of production steps and improvement in definition (fine pitch) of the circuit. That is, it is preferable that at least one of the anisotropic first conductive layer and an anisotropic second conductive layer is made of an anisotropic conductive film. It is more preferable that both of the anisotropic first conductive layer and the anisotropic second conductive layer are made of anisotropic conductive films. The plan shape of the anisotropic first and second conductive layers is not especially limited, and preferably a polygonal shape having sides substantially perpendicular to each other, and more preferably substantially a rectangular shape in view of simplification of the production steps.

It is preferable that the anisotropic first conductive layer has a thickness larger than a thickness of the anisotropic second conductive layer. The electronic first component needs to be reliably connected to the electronic third component via the anisotropic first conductive layer, and the electronic second component needs to be reliably connected to the electronic third component via the anisotropic second conductive layer in addition to the anisotropic first conductive layer. If the thickness of the anisotropic first conductive layer is set to a value preferable when the anisotropic first conductive layer is used for only connecting the electronic first component to the electronic third component and the thickness of the anisotropic second conductive layer is set to a value preferable when the anisotropic second conductive layer is used for only connecting the electronic second component to the electronic third component as in a conventional panel, an amount of the anisotropic conductive materials (the anisotropic first and second conductive materials) provided between the electronic second component and the electronic third component becomes too large, and the anisotropic conductive materials might be insufficiently spread and connection defects might be generated between the electronic second component and the electronic third component. So it is preferable in the present invention that the thicknesses of the anisotropic first and second conductive materials, i.e., the anisotropic first and second conductive layers, are well-balanced. More specifically, the thickness of the anisotropic second conductive layer can be smaller than the thickness of the anisotropic first conductive layer, as mentioned above. As a result, connection defects between the electronic second and third components can be effectively suppressed. Thus, the electronic second and third components can be more reliably connected to each other.

The present invention is a production method of an electronic circuit device including: an electronic first component; an electronic second component; and an electronic third component, the electronic first component and the electronic second component being individually connected to the electronic third component via anisotropic conducive layers, the production method including the steps of:
providing an anisotropic first conductive material on the electronic third component to cover a region where the electronic first component and the electronic second component are to be arranged (mounted) (a step (i));
providing an anisotropic second conductive material on the electronic third component to cover a region where the electronic second component is to be arranged (mounted) or on a surface to which the electronic third component is to be connected of the electronic second component (a step (ii)); and

compression-bonding the electronic second component to the electronic third component via the anisotropic first conductive material and the anisotropic second conductive material.

As a result, accuracy when the anisotropic first and second conductive materials are arranged does not need to be taken into consideration. Accordingly, the distance between the electronic first component and the electronic second component can be decreased, and so a small-sized electronic circuit device can be produced. It is preferable that the compression bonding is a thermocompression bonding. The anisotropic first and second conductive materials show conductivity in the thickness direction and show insulating properties in the planar direction. The anisotropic first and second conductive materials are materials for anisotropic conductive layers, respectively, and these materials are cured to form the anisotropic first and second conductive layers, respectively.

Thus, the present invention also may be a production method of an electronic circuit device including: an electronic first component; an electronic second component; and an electronic third component, the electronic first component and the electronic second component being individually connected to the electronic third component via anisotropic conducive layers,

the production method including the steps of:

providing an anisotropic first conductive material on the electronic third component to cover at least a region where the electronic first component and the electronic second component are to be arranged (mounted) (the step (i));

providing an anisotropic second conductive material on the electronic third component to cover at least a region where the electronic second component is to be arranged (mounted) except for a region where the electronic first component is to be arranged or on the electronic second component to cover at least a region connected to the electronic third component (the step (ii)); and

compression-bonding the electronic second component to the electronic third component via the anisotropic first conductive material and the anisotropic second conductive material.

The production method of the electronic circuit device of the present invention is not especially limited and other steps are not limited as long as it includes these steps. However, it generally includes a step of compression-bonding (preferably, thermocompression-bonding) the electronic first component to the electronic third component via the anisotropic first conductive material. The step (ii) generally follows the step (i).

Preferable embodiments of the production method of the electronic circuit device of the present invention are mentioned below in detail. Various embodiments mentioned below may be employed in combination.

It is preferable that the production method including a step of continuously performing a thermocompression bonding of the electronic first component to the electronic third component via the anisotropic first conductive material and a thermocompression bonding of the electronic second component to the electronic third component via the anisotropic first conductive material and the anisotropic second conductive material. If the electronic first component and the electronic second component are thermocompression-bonded in different steps, the anisotropic first conductive material in a region where the electronic first or second component is to be mounted in a later thermocompression bonding of the two thermocompression bondings might be cured in an earlier thermocompression bonding of the two thermocompression bondings. However, the electronic first and second components are continuously thermocompression-bonded, and thereby the anisotropic first conductive material in a region where the electronic first or second component is to be mounted in the later thermocompression bonding can be kept in an uncured state also in the later thermocompression bonding. Thus, it is also preferable that the production method including a step of performing two thermocompression bondings,

one of the two thermocompression bondings being a thermocompression bonding of the electronic first component to the electronic third component via the anisotropic first conductive material,

the other being a thermocompression bonding of the electronic second component to the electronic third component via the anisotropic first conductive material and the anisotropic second conductive material,

wherein a later thermocompression bonding of the two thermocompression bondings is performed while at least one of the anisotropic first conductive material and the anisotropic second conductive material in a region where the electronic first component or the electronic second component is to be thermocompression-bonded in the later thermocompression bonding is in an uncured state. The above-mentioned “uncured state” means that the material is not necessarily perfectly cured, but it means that the material is hardly cured. From the same viewpoints, the production method may have the following embodiments: it includes a step of performing a thermocompression bonding of the electronic first component to the electronic third component via the anisotropic first conductive material and a thermocompression bonding of the electronic second component to the electronic third component via the anisotropic first and second conductive materials without intervals; and it includes a step of continuously performing a thermocompression bonding of the electronic first component to the electronic third component via the anisotropic first conductive material and a thermocompression bonding of the electronic second component to the electronic third component via the anisotropic first and second conductive materials in the same compression apparatus.

It is preferable that the production method includes a step of performing two thermocompression bondings,

one of the two thermocompression bondings being a thermocompression bonding of the electronic first component to the electronic third component via the anisotropic first conductive material,

the other being a thermocompression bonding of the electronic second component to the electronic third component via the anisotropic first conductive material and the anisotropic second conductive material,

wherein an earlier thermocompression bonding of the two thermocompression bondings is performed while the electronic third component in a region where the electronic first component or the electronic second component is to be arranged in a later thermocompression bonding of the two thermocompression bondings is cooled. If the electronic first and second components are thermocompression-bonded in different steps, the anisotropic first conductive material in a region where the electronic first or second component is to be mounted in the later thermocompression bonding might be cured in the earlier thermocompression bonding. However, the earlier thermocompression bonding is performed while the electronic third component in the region where the electronic first or second component is to be arranged in the later thermocompression bonding is cooled, and thereby the anisotropic first conductive material in a region where the electronic first or second component is to be mounted in the later thermocompression bonding can be kept in an uncured state. Further, a region that is to be cured of the anisotropic first conductive material in the earlier thermocompression bonding can be more decreased. Accordingly, the electronic component that is to be mounted in the later thermocompression bonding and the electronic component that is to be mounted in the earlier thermocompression bonding can be arranged with a smaller distance therebetween. As a result, the electronic circuit device can be downsized. The temperature at which the electronic third component in the region where the electronic first or second component is compression-bonded in the later thermocompression bonding is cooled is not especially limited, and it is preferably 90° C. or less. If the temperature is more than 90° C., curing of the anisotropic first conductive material proceeds dramatically in the earlier thermocompression bonding, the electronic first or second component might be insufficiently thermocompression-bonded in the later thermocompression bonding.

The production method may include a step of simultaneously performing a thermocompression bonding of the electronic first component to the electronic third component via the anisotropic first conductive material and a thermocompression bonding of the electronic second component to the electronic third component via the anisotropic first conductive material and the anisotropic second conductive material. As a result, the electronic first and second components can be thermocompression-bonded via the anisotropic first and second conductive materials in an uncured state, and so the electronic first and second components can be more reliably connected to the electronic third component, compared to the case that the electronic first and second components are thermocompression-bonded in different steps. As mentioned above, the region where the electronic first or second component does not need to be cooled and also the thermocompression apparatus does not need to be provided with a cooling mechanism and the like. As a result, equipment costs can be reduced. The electronic first and the electronic second component can be arranged with a smaller distance therebetween. As a result, the electronic circuit device can be downsized. Further, the production method may have an embodiment in which the production method includes a step of simultaneously performing the thermocompression bonding of the electronic first component to the electronic third component via the anisotropic first conductive material and the thermocompression bonding of the electronic second component to the electronic third component via the anisotropic first and second conductive materials in the same compression bonding apparatus. The term “simultaneously” used herein does not necessarily mean “strictly simultaneously” but means “substantially simultaneously”. One thermocompression bonding may not be overlapped with the other thermocompression bonding in time as long as the difference in time is equivalent to a difference that might be generated when the bondings are performed in one compression bonding apparatus.

The various embodiments mentioned above in the electronic circuit device of the present invention may be appropriately applied to embodiments of components of an electronic circuit device in accordance with the production method of the present invention. Among these, it is preferable that the anisotropic first conductive material has a thickness larger than a thickness of the anisotropic second conductive material from the same viewpoint as in the electronic circuit device of the present invention.

The present invention is a display device including the electronic circuit device of the present invention or a display device including an electronic circuit device produced by the production method of the present invention. According to the present invention, the electronic circuit device can be downsized, and so the frame region of the display device can be more decreased.

### Effect of the Invention

According to the electronic circuit device of the present invention, accuracy when the anisotropic conductive materials that are materials for the anisotropic first and second conductive layers are arranged in the production steps does not need to be taken into consideration. Accordingly, the electronic first and second components can be arranged with a smaller distance therebetween, which leads to downsizing of the electronic circuit device.

### BEST MODES FOR CARRYING OUT THE INVENTION

The present invention is mentioned in more detail below with reference to the following Embodiments using drawings, but not limited only thereto.

### Embodiment 1

FIG. 1 is a schematic view showing a mounting structure of electronic components in an electronic circuit device in accordance with Embodiment 1. FIG. 1(a) is a perspective view schematically showing the mounting structure. FIG. 1(b) is a cross-sectional view showing the mounting structure taken along line X-Y in FIG. 1(a).

As shown in FIG. 1, an electronic circuit device 100 includes: a liquid crystal display panel 16 including a substrate 1a; and a driving IC 8 and a FPC (flexible printed circuit) board 10, mounted on the substrate la with an anisotropic conductive layer 13 therebetween. The liquid crystal display panel 16 corresponds to the electronic third component. The driving IC 8 corresponds to the electronic first component. The FPC board 10 corresponds to the electronic second component.

The liquid crystal display panel 16 has a structure in which liquid crystals 18 are sealed between the substrate 1a and a substrate 1b (substrates constituting the panel) with a sealing member 17. The substrates 1a and 1b generally function as a color filter substrate and a TFT array substrate. Circuit wirings 3 and 4 are arranged on the IC 8 and FPC board 10 side. The circuit wiring 3 includes an output pad 5 for driving IC at a part to which the driving IC 8 is to be connected. The circuit wiring 4 includes an input pad 6 for driving IC at a part to which the driving IC 8 is to be connected, and a connection pad 7 for FPC board at a part to which the FPC board 10 is to be connected.

The driving IC 8 includes a bump electrode 9 with a thickness of about 15 μm on the substrate 1a side. This bump electrode 9 functions as a connecting terminal of the driving IC 8. Thus, the driving IC 8, which is a bare chip, is mounted on the substrate 1a by a COG (chip on glass) method. The driving IC 8 functions as a driver such as a gate driver and a source driver. Accordingly, the driving IC 8 may be what is so-called a COG chip, a liquid crystal driver, a driver IC, and the like. The driving IC 8 may be also an LSI.

In the FPC board 10, a lead electrode 11 with a thickness of about 33 μm is arranged on the substrate 1a side-surface of a base material 12. This lead electrode 11 functions as a connecting terminal of the FPC board 10. The base material 12 is made of a resin such as polyimide. The FPC board 10 has flexibility attributed to substrate 12, which is a flexible film. So the electronic circuit device 100 can be further downsized. On the FPC board 10, electronic components (not shown), for example, IC (LSI) chips such as a power IC and a controller IC, a resistor, and a ceramic condenser, may be mounted.

An anisotropic conductive layer 13a is arranged in mounting regions of the driving IC 8 and the FPC board 10, including a region where the output pad 5, the input pad 6, and the connection pad 7 are arranged. In the mounting region of the FPC board 10 including a region where the connection pad 7 is arranged, an anisotropic conductive layer 13b is arranged. Thus, the anisotropic conductive layer 13 is composed of stacked two layers, i.e., the anisotropic conductive layer 13a, which is a lower layer, and the anisotropic conductive layer 13b, which is an upper layer when the side on which the electronic component is mounted (on the substrate 1a side in the present Embodiment) is defined as a lower direction, and the other side is an upper direction.

The anisotropic conductive layer 13a includes a resin having a storage elastic modulus of 1.5 to 2.0×10⁹ Pa (more specifically, a thermosetting resin such as an epoxy resin, for example) into which particles with conductivity (hereinafter, also referred to as a “conductive particles”) 14a have been dispersed. The anisotropic conductive layer 13b includes a resin having a storage elastic modulus of 1.2 to 1.3×10⁹ Pa (e.g., a thermosetting resin such as an epoxy resin) into which conductive particle 14b have been dispersed. The conductive particle 14a has a diameter of about 3 to 5 μm. The conductive particle 14b has a diameter of about 5 to 10 μm. The content of the conductive particles 14a in the anisotropic conductive layer 13a is about 30 to 50×10³/mm². The content of the conductive particles 14b in the anisotropic conductive layer 13b is about 6 to 10×10³/mm². Such anisotropic conductive layers 13a and 13b show conductivity in the thickness direction (the normal direction of the substrate 1a) and show insulating properties in the planar direction. Thus, the bump electrode 9 of the driving IC 8 is electrically connected to the output pad 5 and the input pad 6 through the conductive particles 14a, and further the driving IC 8 is thermocompression-bonded (fixed) to the substrate 1a with the resin contained in the anisotropic conductive layer 13a. The lead electrode 11 of the FPC board 10 is electrically connected to the connection pad 7 via the conductive particles 14a and 14b contained in the anisotropic conductive layers 13a and 13b. The FPC board 10 is thermocompression-bonded (fixed) to the substrate 1a, similarly to the driving IC 8. Thus, the anisotropic conductive layers 13a and 13b, which are different anisotropic conductive layers, are interposed between the lead electrode 11 of the FPC board 10 and the connection pad 7 of the substrate 1a.

The conductive particles 14b are larger than the conductive particles 14a. Accordingly, the lead electrode 11 is electrically connected to the connection pad 7 mainly via the conductive particles 14b.

The anisotropic conductive layer 13a has a storage elastic modulus of 1.5 to 2.0×10⁹ Pa. The anisotropic conductive layer 13b has a storage elastic modulus of 1.2 to 1.3×10⁹ Pa. As a result, the anisotropic conductive layers 13a and 13b can adhere very tightly to the driving IC 8 and the FPC board 10, respectively.

The storage elastic modulus can be measured by a dynamic viscoelastic test using Solid analyzer RSA-2, product of Rheometric Scientific instruments as a measurement apparatus. The frequency is generally about 0.1 to 100 rad/sec in view of apparatus performances.

A production method of the electronic circuit device 100 is mentioned below with reference to FIG. 2. FIGS. 2(a) to 2(d) are perspective views schematically showing production steps of the electronic circuit device in accordance with Embodiment 1.

As shown in FIG. 2(a), the liquid crystal display panel 16 including the circuit wirings 3 and 4 at an extending part 2 of the substrate 1a is prepared by a common method. The substrate 1a is prepared in the following manner: components such as a switching element, a bus wiring (a gate wiring and a source wiring), and a pixel electrode are formed in a matrix pattern within a sealing member 17 on the insulating substrate such as a glass substrate, and the circuit wirings 3 and 4 are arranged at the extending part 2 of the insulating substrate such as a glass substrate. Thus, the substrate 1a is generally a TFT array substrate, and the substrate 1b is generally a color filter substrate. The circuit wirings 3 and 4, and the bus wiring are formed in the same wiring layer. The circuit wiring 3 is connected to and may be integrated with the bus wiring. In the substrate 1b, components such as a common electrode and a color filter layer are formed within the sealing member 17 of an insulating substrate such as a glass substrate. Liquid crystals (e.g., nematic liquid crystals) 18 are sealed between the substrates 1a and 1b with the sealing member 17. The material for the insulating substrate is generally made of glass, but may be a transparent resin, for example.

As shown in FIG. 2(b), an ACF (anisotropic conductive film) 15a (a material that gives the anisotropic conductive layer 13a by being cured) is provided on the substrate 1a to cover a region where the IC driving 8 and the FPC board 10 are to be mounted (including a region where the circuit wirings 3 and 4 are arranged) (ACF 15a—providing step). Similarly, an ACF 15b (a material that gives the anisotropic conductive layer 13b by being cured) is provided on the FPC board 10 to cover a mounting surface (where the lead electrode 11 is arranged) of the FPC board 10 (ACF 15b—providing step). It is preferable that the ACF 15a is a thermosetting resin film, e.g. , an epoxy resin film into which the conductive particles 14a have been dispersed, and that the ACF 15a has a thickness of about 15 to 25 μm. If the ACF 15a has a thickness of more than 25 μm, the ACF 15a is insufficiently spread, which might result in failure of the compression bonding. If the ACF 15a has a thickness of less than 15 μm, the ACF 15a is insufficiently provided, and so connection reliability might be deteriorated. It is preferable that the ACF 15b is a film prepared by dispersing the conductive particles 14b into a thermosetting resin such as an epoxy resin and the ACF 15b has a thickness of about 10 to 20 μm. If the ACF 15b has a thickness of more than 20 μm, the ACF 15b is insufficiently spread, which might result in failure of the compression bonding. If the ACF 15b has a thickness of less than 10 μm, the ACF 15b is insufficiently provided, and so connection reliability might be deteriorated

The thickness of the ACF 15b is conventionally set to about 20 to 30 μm. According to the present Embodiment, the thickness of the ACF 15b is smaller than the conventional thickness by the thickness of the ACF 15a because as mentioned below, the ACF 15a is provided in the region where the ACF 15b is to be compression-bonded before the ACF 15b is provided. So connection defects caused when the ACF 15a or 15b is provided too much and so insufficiently spread can be suppressed. Thus, it is preferable that the thickness of the ACF (the ACF 15b in the present Embodiment) provided for one electronic component (the FPC board 10 in the present Embodiment) is smaller than the thickness of the ACF (the ACE 15a in the present Embodiment) provided for at least two electronic components (the driving IC 8 and the FPC board 10 in the present Embodiment).

The ACF 15b may be provided on the ACF 15a of the substrate 1a to cover the mounting region of the FPC board 10.

Then, a step of mounting the driving IC 8 and the FPC board 10 (thermocompression bonding step) is performed. First, the driving IC 8 is mounted on (thermocompression-bonded to) the liquid crystal display panel 16. More specifically, as shown in FIG. 2(c), the bump electrode 9 of the driving IC 8 is aligned to the output pad 5 and the input pad 6, and then, the driving IC 8 is thermocompression-bonded to the circuit wirings 3 and 4 under specific conditions. The thermocompression bonding is performed under the following conditions, for example: a connection temperature of 180 to 190° C.; a connection time of 5 to 15 seconds; a pressure of 60 to 80 MPa. As a result, the ACF 15a in the region where the driving IC 8 is mounted and its peripheral region can be perfectly cured, and the ACF 15a in the region where the FPC board 10 is to be mounted can be kept in an uncured state.

It is preferable that the driving IC 8 is thermocompression-bonded to the panel while the substrate 1a in a region where the FPC board 10 is to be mounted is cooled by a cooling mechanism and the like (more specifically, cooled at about 80° C., for example). As a result, an area of a region where the ACF 15a is cured can be more decreased in a region other than the region where the driving IC 8 is mounted. Accordingly, the region where the FPC board 10 is mounted can be closer to the region where the driving IC 8 is mounted. So the electronic circuit device 100 can be more downsized. In addition, the region where the FPC board 10 is to be mounted can be more reliably kept in an uncured state even after the thermocompression bonding of the driving IC 8.

Then, the FTC board 10 is mounted (thermocompression-bonded) to the liquid crystal display panel 16. More specifically, as shown in FIG. 2(d), the lead electrode 11 of the FPC board 10 is aligned to the connection pad 7, and the FTC board 10 is thermocompression-bonded to the circuit wiring 4 in the state where the ACFs 15a and 15b overlap with each other. This thermocompression bonding is performed under the following conditions, for example: a connection temperature of 180 to 190° C.; a connection time of 10 to 20 seconds; and a pressure of 1.5 to 2.5 MPa. As a result, a part of the ACF 15a that has been kept in an uncured state is perfectly cured together with the ACF 15b. The ACF 15a and 15b do not need to be kept in an uncured state, and so the substrate 1a does not need to be cooled by a cooling mechanism and the like, either.

It is preferable that the driving IC 8 and the FTC board 10 are continuously thermocompression-bonded using a plurality of bonding apparatuses, a thermocompression bonding apparatus including a plurality of compression bonding units and the like. As a result, the ACF 15a in the region where the FTC board 10 is to be mounted can be effectively kept in an uncured state until the FTC board 10 is thermocompression-bonded. In order to perform thermocompression-bonding of the driving IC 8 and the FPC board 10 more quickly, that is, with a smaller interval, it is preferable that the driving IC 8 and the FPC board 10 are continuously thermocompression-bonded with a compression bonding apparatus including a plurality of compression bonding units.

It is preferable that the driving IC 8 and the FPC board 10 are substantially simultaneously thermocompression-bonded with a compression bonding apparatus including a plurality of compression bonding units, and the like. As a result, the driving IC 8 and the FPC board 10 can be more reliably connected to the liquid crystal display panel 16, and the reliability of the electronic circuit device 100 can be improved. As mentioned above, the compression bonding apparatus does not need to be equipped with a cooling mechanism, and so equipment costs can be reduced. In addition, the driving IC 8 and the FPC board 10 can be thermocompression-bonded to the liquid crystal display panel 16 via the ACFs 15a and 15b each in an uncured state. So the region where the FPC board 10 is mounted can be closer to the region where the driving IC 8 is mounted. As a result, the electronic circuit device 100 can be further downsized.

Thus, the electronic circuit device 100 can be easily produced.

According to the electronic circuit device 100, the anisotropic conductive layer 13a and the anisotropic conductive layer 13b are provided to overlap with each other from the liquid crystal display panel 16 side in the mounting region of the FPC board 10. Accordingly, accuracy when the ACFs 15a and 15b are provided does not need to be taken into consideration. The distance between the driving IC 8 and the FPC board 10 (Al in FIG. 1(a)) can be determined by taking only accuracy when the electronic component such as the driving IC 8 and the FPC board 10 are mounted into consideration. As a result, the distance A1 can be shorter than the distance A2 shown in FIG. 4(a). So, compared to the conventional electronic circuit device where the accuracy when the ACFs are provided and the accuracy when the electronic components are mounted are both taken into consideration, the electronic circuit device 100 can be reduced in size. Accordingly, if the electronic circuit device 100 is applied to the display device such as a liquid crystal display device, a frame region of the substrates constituting the panel can be decreased, and so the obtained display device has a small frame region.

In addition to the above-mentioned production method of the electronic circuit device 100, a production method shown in FIG. 3 may be employed as a production method of the electronic circuit device 100. FIGS. 3(a) to 3(c) are perspective views schematically showing the electronic circuit device in Embodiment 1 in accordance with other production steps.

As shown in FIG. 3(a), similarly to the above-mentioned method, an ACF (anisotropic conductive film) 15b is provided on a substrate 1a to cover a region where a driving IC 8 and a FPC board 10 are to be arranged (an ACF 15b—providing step). Further, an ACF (anisotropic conductive film) 15a is provided to cover a mounting surface (surface where a bump electrode 9 is arranged) of the driving IC 8 (an ACF 15a—providing step). It is preferable that the thickness of the ACF 15b is equivalent to a thickness of the conventional ACF for FPC board 10 connection, and more specifically, about 20 to 30 μm. If the ACF 15b has a thickness of more than 30 μm, the ACF 15b is insufficiently spread, which might result in failure of compression bonding. If the ACF 15b has a thickness of less than 20 μm, the ACF 15b is insufficiently provided, and so connection reliability might be deteriorated.

It is preferable that the ACF 15a has a thickness smaller than a thickness of a conventional ACF for driving IC 8 connection. The thickness of the ACF 15a is smaller than the conventional thickness by the thickness of the ACF 15b. More specifically, it is preferable that the thickness of the ACF 15a is about 5 to 10 μm. If the thickness of the ACF 15a is more than 10 μm, the ACF 15a is insufficiently spread, which might result in failure of compression bonding. If the thickness of the ACF 15a is less than 5 μm, the ACF 15a is insufficiently provided, and so connection reliability might be deteriorated.

The ACF 15a may be provided on the ACF 15b of the substrate 1a to cover a region where the driving IC 8 is to be arranged.

Then, a step of mounting (thermocompression-bonding) the FPC substrate 10 and the driving IC 8 is performed. First, the FPC board 10 is mounted on (thermocompression-bonded to) the liquid crystal display panel 16. More specifically, as shown in FIG. 3(b), a lead electrode 11 of the FPC board 10 is aligned to the connection pad 7, and the FPC board 10 is thermocompression-bonded to the circuit wiring 4 under specific conditions. The thermocompression bonding is performed under the following conditions, for example: a connection temperature of 180 to 190° C.; a connection time of 10 to 20 seconds; and a pressure of 1.5 to 2.5 MPa. As a result, the ACF 15b in a region where the FPC board 10 is mounted and its peripheral region can be perfectly cured, but the ACF 15b in a region where the driving IC 8 is to be arranged can be kept in an uncured state.

Similarly to the above-mentioned method, it is preferable that the FPC board 10 is thermocompression-bonded to the panel while the substrate 1a in a region where the driving IC 8 is to be mounted is cooled by a cooling mechanism and the like (more specifically, cooled at about 80° C., for example).

Then, the driving IC 8 is mounted on (thermocompression-bonded to) the liquid crystal display panel 16. More specifically, as shown in FIG. 3(c), the bump electrode 9 is aligned to the output pad 5 and the input pad 6, and then, the driving IC 8 is thermocompression-bonded to the circuit wiring 3 in the state where the ACFs 15a and 15b overlap with each other under specific conditions. The thermocompression bonding is performed under the following conditions, for example: a connection temperature of 180 to 190° C.; a connection time of 5 to 15 seconds; and a pressure of 60 to 80 MPa. As a result, a part of the ACF 15b which has been kept in an uncured state is perfectly cured together with the ACF 15a. The ACF 15a and 15b do not need to be kept in an uncured state, and so the substrate 1a does not need to be cooled by a cooling mechanism and the like, either.

Similarly to the above-mentioned method, the FPC board 10 and the driving IC 8 are thermocompression-bonded continuously with a plurality of compression bonding apparatuses, a compression bonding apparatus including a plurality of compression bonding units and the like. According to this, the ACF 15b in a region where the driving IC 8 is to be mounted can be effectively kept in an uncured state until the driving IC 8 is thermocompression-bonded to the panel. From the same viewpoint as in the above-mentioned method, it is preferable that the driving IC 8 and the FPC board 10 are continuously thermocompression-bonded with a compression bonding apparatus including a plurality of compression bonding units.

Similarly to the above-mentioned method, in order to effectively improve reliability of the electronic circuit device 100 and reduce equipment costs, and further downsize the electronic circuit device 100, it is preferable that the FPC board 10 and the driving IC 8 are thermocompression-bonded substantially simultaneously with a compression bonding apparatus including a plurality of compression bonding units and the like.

Also by this method, the electronic circuit apparatus 100 can be easily produced.

According to the present Embodiment, the anisotropic conductive layers 13a and 13b are formed of the ACFs 15a and 15b, and the anisotropic conductive layers 13a and 13b may be formed of other anisotropic conductive materials such as an anisotropic conductive paste (ACP).

The electronic circuit device 100 may have the following structure: in addition to the driving IC 8 and the FPC board 10, which are the electronic first and second components, other electronic components, e.g., a passive element such as an LED, a condenser, and a sensor, are mounted on the substrate 1a, which is the electronic third component, via the anisotropic conductive layer(s) 13a and/or 13b.

In the electronic circuit device 100, the liquid crystal display panel 16 where the extending part 2 is arranged on one side of the substrate 1a. Positions where the extending part 2, the driving IC 8, and the FPC board 10 are arranged are not especially limited. That is, the electronic circuit device 100 may have an embodiment in which the driving IC 8 and the FPC board 10 are mounted at an L-shaped extending part arranged on two sides of the substrate 1a, or may have an embodiment in which the driving IC 8 and the FPC board 10 are individually arranged on extending parts arranged on one side of the substrates 1a and 1b, respectively.

According to Embodiment 1, the electronic circuit device of the present invention is applied to the liquid crystal display device. However, the electronic circuit device of the present invention may be applied to not only the liquid crystal display device but also the following various display devices, for example: an organic electroluminescence (EL) display device, an inorganic EL display device, a plasma display panel (PDP), a vacuum fluorescence display (VFD) device, and an electronic paper. The electronic circuit device of the present invention can be applied to not only the display devices but also various electronic apparatuses such as a cellular phone, a PDA (personal digital assistant), OA equipment, and a personal computer. That is, the present invention may have an embodiment in which two ICs are mounted on a FPC board via an anisotropic conductive layer having a multi-layer structure, an embodiment in which an IC and a FPC board are mounted on a PWB via an anisotropic conductive layer having a multi-layer structure, and the like.

According to the present Embodiment, the electronic component that is mounted on the panel via different two anisotropic conductive layers is either the driving IC or the FPC board. In the present invention, however, the number of the electronic component that is mounted on the panel via a plurality of anisotropic conductive layers is not especially limited, and it may be two or more. FIGS. 5(a) and 5(b) are perspective views schematically showing another mounting structure of electronic components in the electronic circuit device in accordance with Embodiment 1. An electronic circuit device 100 in the present Embodiment may have the following structure, as shown in FIG. 5(a), for example: an electronic component 19c is connected to a component (electronic component 19X) via an anisotropic conductive layer 13c; an electronic component 19d is connected to the electronic component 19X via the anisotropic conductive layer 13c and an anisotropic conductive layer 13d stacked in this order from the electronic component 19X side; an electronic component 19e is connected to the electronic component 19X via the anisotropic conductive layer 13c and an anisotropic conductive layer 13e stacked in this order from the electronic component 19X side; and an electronic component 19f is connected to the electronic component 19X via the anisotropic conductive layer 13c and an anisotropic conductive layer 13f stacked in this order from the electronic component 19X side.

The electronic circuit device 100 shown in FIG. 5(a) can be prepared in the following manner, for example: a step of providing a material for the anisotropic conductive layer 13c (for example, an anisotropic conductive film) on the electronic component 19X to cover a region where the electronic components 19c, 19d, 19e, and 19f are to be mounted, and then, successively providing materials for the anisotropic conductive layer 13d, the anisotropic conductive layer 13e, and the anisotropic conductive layer 13f (for example, anisotropic conductive films) is performed; and then, continuously the electronic components 19c, 19d, 19e, and 19f are connected to the electronic component 19X.

The electronic circuit device 100 of the present Embodiment may have the following structure, as shown in FIG. 5(b), for example. An electronic component 19g is connected to a component (electronic component 19Y) via an anisotropic conductive layer 13g; an electronic component 19h is connected to the electronic component 19Y via the anisotropic conductive layer 13g and an anisotropic conductive layer 13h stacked in this order from the electronic component 19Y side; an anisotropic component 19i is connected to the electronic component 19Y via the anisotropic conductive layer 13h and an anisotropic conductive layer 13i stacked in this order from the electronic component 19Y side; and an electronic component 19j is connected to the electronic component 19Y via the anisotropic conductive layer 13i and an anisotropic conductive layer 13j stacked in this order from the electronic component 19Y side. Thus, the electronic circuit device 100 of the present Embodiment may have a structure in which the anisotropic conductive layers 13g, 13h, 13i, and 13j are stacked in the above-mentioned manner.

The electronic circuit device 100 shown in FIG. 5(b) can be produced in the following manner, for example. A material for the anisotropic conductive layer 13g (e.g., an anisotropic conductive film) is provided on the electronic component 19Y to cover a region where the electronic components 19g and 19h are to be arranged; a material for the anisotropic conductive layer 13h (e.g., an anisotropic conductive film) is provided on the electronic component 19Y to cover a region where the electronic components 19h and 19i are to be arranged; a material for the anisotropic conductive layer 13i (e.g., an anisotropic conductive film) is provided on the electronic component 19Y to cover a region where the electronic components 19i and 19j are to be arranged; a material for the anisotropic conductive layer 13j (e.g., an anisotropic conductive film) is provided on the electronic component 19Y to cover a region where the electronic component 19j is to be arranged; and the electronic components 19g, 19h, 19i, and 19j are continuously connected to the electronic component 19Y.

The present application claims priority to Patent Application No. 2007-42701 filed in Japan on Feb. 22, 2007 under the Paris Convention and provisions of national law in a designated State, the entire contents of which are hereby incorporated by reference.

### BRIEF DESCRIPTION OF DRAWINGS

FIG. 1 is a schematic view of a mounting structure of electronic components in the electronic circuit device in accordance with Embodiment 1. FIG. 1(a) is a perspective view schematically showing the mounting structure. FIG. 1(b) is a cross-sectional view showing the mounting structure taken along line X-Y in FIG. 1(a).

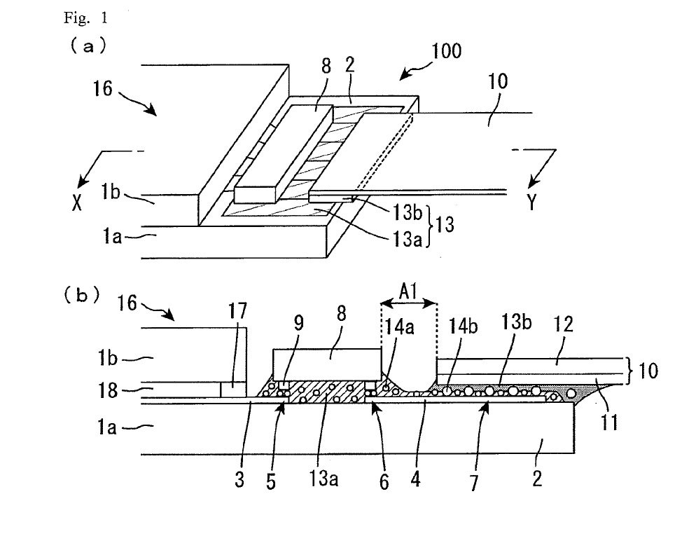

FIGS. 2(a) to 2(d) are perspective views schematically showing production steps of the electronic circuit device in accordance with Embodiment 1.

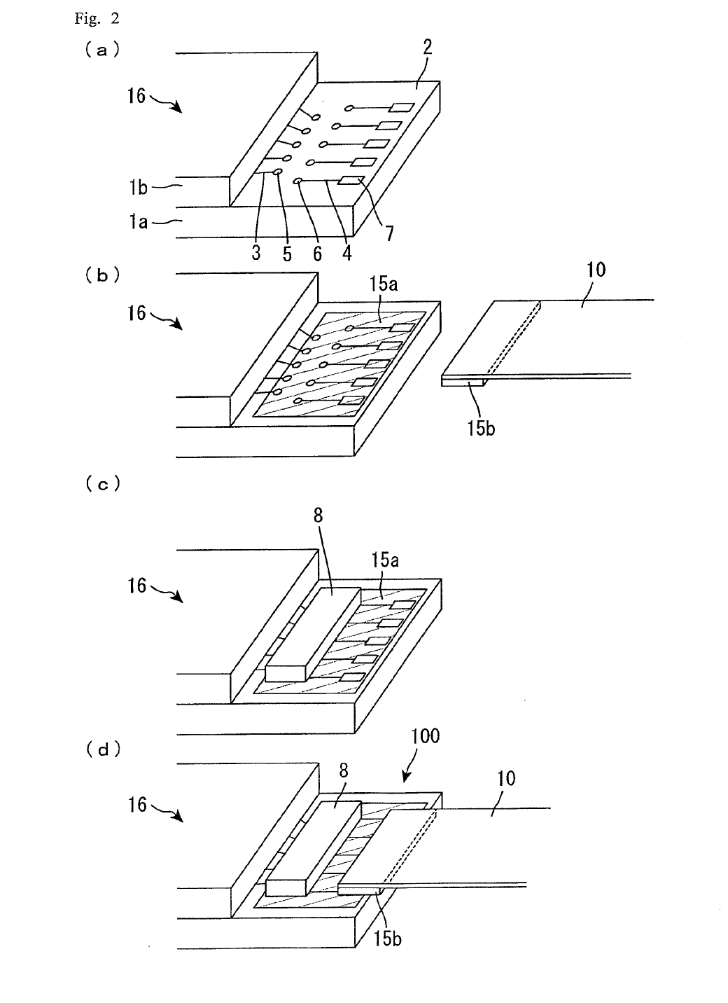

FIGS. 3(a) to 3(c) are perspective views schematically showing other production steps of the electronic circuit device in accordance with Embodiment 1.

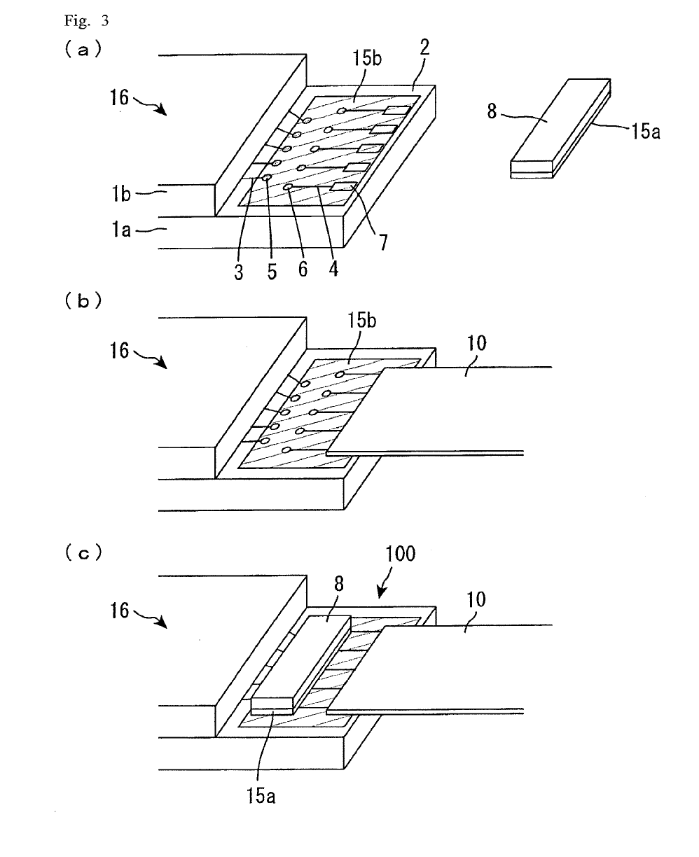

FIG. 4 is a schematic view showing a mounting structure of electronic components in the conventional liquid crystal display panel. FIG. 4(a) is a perspective view schematically showing the mounting structure. FIG. 4(b) is a cross-sectional view showing the mounting structure taken along line P-Q in FIG. 4(a).

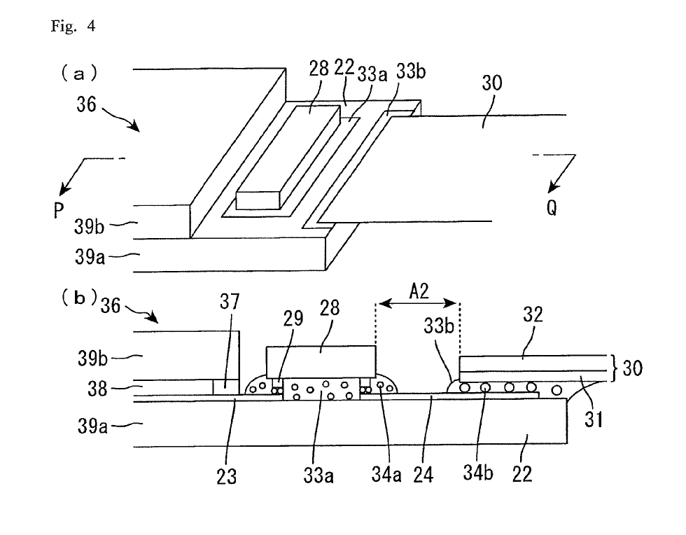

FIGS. 5(a) and 5(b) are perspective views schematically showing another mounting structure of electronic components in the electronic circuit device in accordance with Embodiment 1.

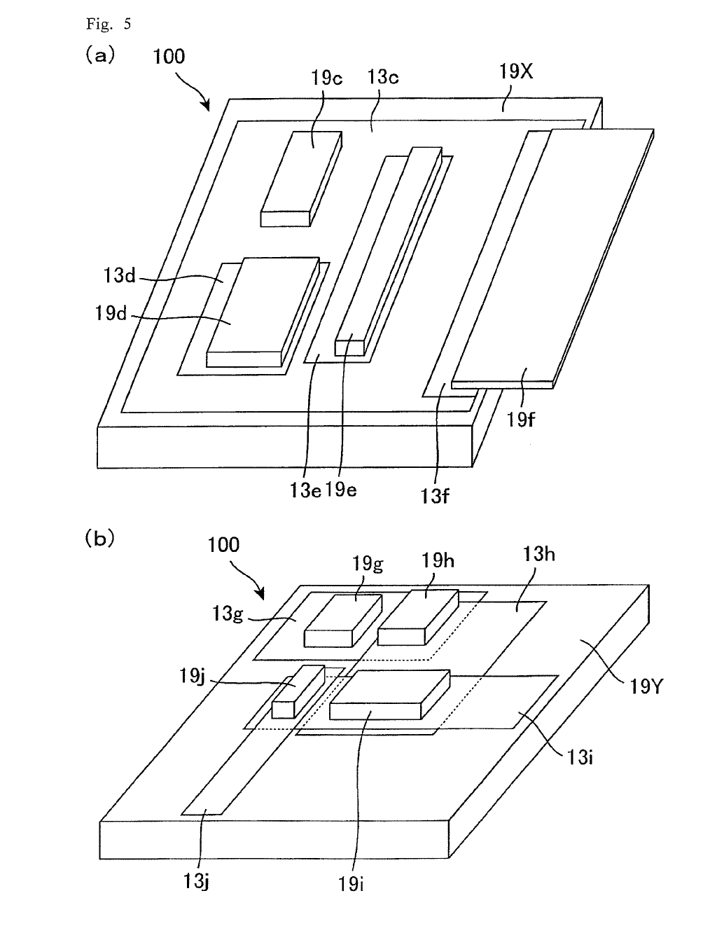

### EXPLANATION OF NUMERALS AND SYMBOLS

1a, 1b: Substrate
2, 22: Extending part
3, 4, 23, 24: Circuit wiring
5: Output pad for driving IC
6: Input pad for driving IC
7: Connection pad for FPC board
8, 28: Driving IC
9, 29: Bump electrode
10, 30: FPC board
11, 31: Lead electrode
12, 32: Base material
13a, 13b, 13c, 13d, 13e, 13f, 13g, 13h, 13i, 13j, 13, 33a, 33b: Anisotropic conductive layer
14a, 14b, 34a, 34b: Conductive particles (particles with conductivity)
15a, 15b: Anisotropic conductive film (ACF)
16, 36: Liquid crystal display panel
17, 37: Sealing member
18, 38: Liquid crystal
19c, 19d, 19e, 19f, 19g, 19h, 19i, 19j, 19Y, 19X: Electronic component
39a, 39b: Glass substrate
100: Electronic circuit device
A1, A2: Distance between driving IC and FPC board

1. An electronic circuit device comprising:
an electronic first component;
an electronic second component;
an electronic third component;
an anisotropic first conductive layer; and
an anisotropic second conductive layer,
wherein the electronic first component is connected to the electronic third component via the anisotropic first conductive layer, and
the electronic second component is connected to the electronic third component via the anisotropic first conductive layer and the anisotropic second conductive layer,
the anisotropic first conductive layer and the anisotropic second conductive layer being stacked in this order on the electronic third component.

2. The electronic circuit device according to claim 1,
wherein the electronic first component and the electronic second component are different in kind.

3. The electronic circuit device according to claim 1,
wherein the electronic third component is a wiring board.

4. The electronic circuit device according to claim 1,
wherein the electronic first component and the electronic second component are different in surface configuration.

5. The electronic circuit device according to claim 1,
wherein one of the electronic first component and the electronic second component is a semiconductor element and the other is a flexible printed board, and
the electronic third component is a substrate constituting a panel.

6. The electronic circuit device according to claim 1,
wherein the anisotropic first conductive layer and the anisotropic second conductive layer are different in kind.

7. The electronic circuit device according to claim 1,
wherein the anisotropic first conductive layer and the anisotropic second conductive layer are different in storage elastic modulus.

8. The electronic circuit device according to claim 1,
wherein one of the anisotropic first conductive layer and the anisotropic second conductive layer has a storage elastic modulus of 1.5 to 2.0×10⁹ Pa and the other has a storage elastic modulus of 1.2 to 1.3×10⁹ Pa.

9. The electronic circuit device according to claim 1,
wherein the electronic first component is a semiconductor element,
the electronic second component is a flexible printed board, the electronic third component is a substrate constituting a panel,
the anisotropic first conductive layer has a storage elastic modulus of 1.5 to 2.0×10⁹ Pa, and
the anisotropic second conductive layer has a storage elastic modulus of 1.2 to 1.3×10⁹ Pa.

10. The electronic circuit device according to claim 1,
wherein the electronic first component is a flexible printed board,
the electronic second component is a semiconductor element,
the electronic third component is a substrate constituting a panel,
the anisotropic first conductive layer has a storage elastic modulus of 1.2 to 1.3×10⁹ Pa, and
the anisotropic second conductive layer has a storage elastic modulus of 1.5 to 2.0×10⁹ Pa.

11. The electronic circuit device according to claim 1,
wherein at least one of the anisotropic first conductive layer and the anisotropic second conductive layer is made of an anisotropic conductive film.

12. The electronic circuit device according to claim 1,
wherein the anisotropic first conductive layer has a thickness larger than a thickness of the anisotropic second conductive layer.

13. A production method of an electronic circuit device including: an electronic first component; an electronic second component; and an electronic third component,
the electronic first component and the electronic second component being individually connected to the electronic third component via anisotropic conducive layers,
the production method comprising the steps of:
providing an anisotropic first conductive material on the electronic third component to cover a region where the electronic first component and the electronic second component are to be arranged;
providing an anisotropic second conductive material on the electronic third component to cover a region where the electronic second component is to be arranged or on a surface to which the electronic third component is to be connected of the electronic second component; and
compression-bonding the electronic second component to the electronic third component via the anisotropic first conductive material and the anisotropic second conductive material.

14. The production method according to claim 13, comprising a step of continuously performing a thermocompression bonding of the electronic first component to the electronic third component via the anisotropic first conductive material and a thermocompression bonding of the electronic second component to the electronic third component via the anisotropic first conductive material and the anisotropic second conductive material.

15. The production method according to claim 13, comprising a step of performing two thermocompression bondings,
one of the two thermocompression bondings being a thermocompression bonding of the electronic first component to the electronic third component via the anisotropic first conductive material,
the other being a thermocompression bonding of the electronic second component to the electronic third component via the anisotropic first conductive material and the anisotropic second conductive material,
wherein a later thermocompression bonding of the two thermocompression bondings is performed while at least one of the anisotropic first conductive material and the anisotropic second conductive material in a region where the electronic first component or the electronic second component is to be thermocompression-bonded in the later thermocompression bonding is in an uncured state.

16. The production method according to claim 13, comprising a step of performing two thermocompression bondings,
one of the two thermocompression bondings being a thermocompression bonding of the electronic first component to the electronic third component via the anisotropic first conductive material,
the other being a thermocompression bonding of the electronic second component to the electronic third component via the anisotropic first conductive material and the anisotropic second conductive material,
wherein an earlier thermocompression bonding of the two thermocompression bondings is performed while the electronic third component in a region where the electronic first component or the electronic second component is to be arranged in a later thermocompression bonding of the two thermocompression bondings is cooled.

17. The production method according to claim 13, comprising a step of simultaneously performing a thermocompression bonding of the electronic first component to the electronic third component via the anisotropic first conductive material and a thermocompression bonding of the electronic second component to the electronic third component via the anisotropic first conductive material and the anisotropic second conductive material.

18. The electronic circuit device according to claim 13,wherein the anisotropic first conductive material has a thickness larger than a thickness of the anisotropic second conductive material.

19. A display device comprising the electronic circuit device according to claim 1.

20. A display device comprising an electronic circuit device produced by the production method according to claim 13.
